(19) United States
(12) Patent Application Publication
(10) Pub. No.: US 2026/0076008 A1
(43) Pub. Date: Mar. 12, 2026

(54) DISPLAY PANEL AND METHOD OF FABRICATING THE SAME

(71) Applicant: AUO Corporation, Hsinchu City (TW)

(72) Inventors: Yao-Shan Chang, Hsinchu City (TW); Yu-Syuan Lin, Hsinchu City (TW); Chun-Liang Lin, Hsinchu City (TW)

(73) Assignee: AUO Corporation, Hsinchu City (TW)

(21) Appl. No.: 19/312,269

(22) Filed: Aug. 27, 2025

(30) Foreign Application Priority Data
Sep. 6, 2024 (TW) 113133849

(51) Int. Cl. H10H 29/851; H01L 25/075; H10H 29/01; H10H 29/24

(52) U.S. Cl. CPC H10H 29/8515; H10H 29/0361; H10H 29/24; H10W 90/00

(57) ABSTRACT

A display panel including a first substrate, a second substrate, a first bank structure, a second bank structure, a light-emitting element, and a color conversion pattern is provided. The first bank structure is disposed on the first substrate. The second bank structure is disposed on the second substrate. The light-emitting element is disposed in a first accommodation space defined by the first bank structure. The color conversion pattern includes a first portion and a second portion overlapping each other and separated from each other. The first portion is disposed on the first substrate and covers the light-emitting element. The second portion is disposed on the second substrate and located in a second accommodation space defined by the second bank structure. In a direction perpendicular to a stacking direction of the two substrates, a second width of the second portion is less than a first width of the first portion.

### CROSS-REFERENCE TO RELATED APPLICATION

This application claims the priority benefit of Taiwan application serial no. 113133849, filed on Sep. 6, 2024. The entirety of the above-mentioned patent application is hereby incorporated by reference herein and made a part of this specification.

### BACKGROUND

### Technical Field

The disclosure relates to a display panel, and more particularly to a display panel provided with a light-emitting element.

### Description of Related Art

Recently, light-emitting diode (LED) panels have gained increasing popularity due to advantages such as easy color calibration, long emission lifespan, and absence of image burn-in. To meet the demand for full-color display, a structural design incorporating color conversion technology has been proposed. For example, different display pixels may be configured with different color conversion layers based on their respective display colors and operate under illumination from LEDs of the same color. Generally, the color conversion layer must have sufficient thickness to achieve good light conversion efficiency. However, increasing the thickness of the color conversion layer not only raises the fabrication difficulty of the bank structure but also degrades the light extraction efficiency of the converted light generated by the color conversion layer.

### SUMMARY

The disclosure provides a display panel with both excellent color conversion efficiency and light extraction efficiency.

The disclosure further provides a method of fabricating a display panel, which offers a larger process margin and higher production yield.

A display panel of the disclosure includes a first substrate, a second substrate, a first bank structure, a second bank structure, a light-emitting element, and a color conversion pattern. The first substrate and the second substrate overlap each other along a stacking direction. The first bank structure is disposed on the first substrate and defines a first accommodation space. The second bank structure is disposed on the second substrate and defines a second accommodation space. The light-emitting element is disposed on the first substrate and located in the first accommodation space. The color conversion pattern is disposed between the first substrate and the second substrate, and includes a first portion and a second portion overlapping each other and separated from each other. The first portion is disposed on the first substrate and covers the light-emitting element. The second portion is disposed on the second substrate and is located in the second accommodation space. The first portion and the second portion respectively have a first width and a second width along a direction perpendicular to the stacking direction, and the second width is less than the first width.

A method of fabricating a display panel of the disclosure includes transferring a light-emitting element onto a first substrate, forming a first bank structure on the first substrate, forming a second bank structure on a second substrate to define a second accommodation space, forming a first portion of a color conversion pattern on the first substrate to cover the light-emitting element, forming a second portion of the color conversion pattern in the second accommodation space on the second substrate, and assembling the first substrate and the second substrate along a stacking direction such that the first portion and the second portion of the color conversion pattern overlap each other and are separated from each other. The light-emitting element is located in the first accommodation space defined by the first bank structure. The first portion and the second portion respectively have a first width and a second width along a direction perpendicular to the stacking direction, and the second width is less than the first width.

Based on the above, in a display panel according to an embodiment of the disclosure, a color conversion pattern is provided on a light-emitting side of a light-emitting element, and the color conversion pattern is composed of a first portion and a second portion that are separated from each other. The first portion directly covers the light-emitting element on the first substrate. The overlapping relationship among the first portion, the second portion, and the light-emitting element along a stacking direction of the first substrate and the second substrate ensures the color conversion efficiency of the display panel. In a direction perpendicular to the stacking direction, since a width of the second portion is less than a width of the first portion, a part of the first portion surrounding the sidewall of the light-emitting element is not blocked by the second portion. As such, the converted light generated by the light emitted from the light-emitting element and passing through the part of the first portion is not blocked by the second portion, thereby effectively improving the overall light extraction efficiency of the display panel. On the other hand, since the first portion and the second portion of the color conversion pattern are respectively formed on the first substrate and the second substrate, an excessive height of the bank structure used to define the accommodating space can be avoided, thereby reducing manufacturing complexity. In other words, the segmented design of the color conversion pattern increases the process margin of the display panel, thereby improving its production yield.

### BRIEF DESCRIPTION OF THE DRAWINGS

FIG. 1 is a schematic cross-sectional view of a display panel according to an embodiment of the disclosure.

FIG. 2A to FIG. 2I are schematic cross-sectional views illustrating a manufacturing process of the display panel in FIG. 1.

FIG. 3 is a block diagram illustrating the manufacturing process of the display panel in FIG. 1.

### DESCRIPTION OF THE EMBODIMENTS

As used herein, the terms “approximately,” “about,” “substantially,” or “essentially” include the stated values as well as average values within an acceptable deviation range as would be determined by a person skilled in the art, taking into account specific quantities of measurement and the errors associated with measurement (i.e., limitations of the measurement system). For example, “about” may refer to within one or more standard deviations from the stated value, or within ±30%, ±20%, ±15%, ±10%, or ±5%. Furthermore, depending on the nature of the measurement, cutting process, or other relevant properties, the terms “approximately,” “about,” “substantially,” or “essentially” may be interpreted with a selectively acceptable deviation range or standard deviation, and a single standard deviation does not necessarily apply to all properties.

In the drawings, for clarity, the thicknesses of layers, films, panels, and regions are exaggerated. It should be understood that when components such as layers, films, regions, or substrates are described as being “on” or “connected to” another component, they may be directly on or connected to the other component, or intermediate components may also be present. Conversely, when components are described as being “directly on” or “directly connected to” another component, no intermediate components are present. As used herein, “connected” may refer to physical and/or electrical connection. Additionally, “electrically connected” may still allow for other components to exist between the two elements.

Moreover, relative terms such as “lower” or “bottom” and “upper” or “top” may be used herein to describe the relationship between components as shown in the FIG. s. It should be understood that such relative terms are intended to encompass different orientations of the device beyond those shown in the drawings. For example, if a device in a drawing is flipped, the component described as being “below” another component may now be positioned “above” it. Thus, exemplary terms such as “lower” may include both “lower” and “upper” orientations, depending on the specific orientation in the FIG. s. Similarly, a component described as being “under” or “beneath” another may also be situated “over” or “above” it if the FIG. is flipped. Therefore, exemplary terms like “above”or “below”may include both orientations.

The exemplary embodiments described herein are referenced to schematic cross-sectional views, which are idealized examples. Variations in the illustrated shapes due to, for example, manufacturing techniques and/or tolerances are to be expected. Therefore, the embodiments described herein should not be construed as limited to the specific shapes illustrated, but rather include shape deviations that result from manufacturing. For instance, regions shown or described as flat may exhibit rough and/or nonlinear characteristics. Additionally, sharp corners shown in the drawings may in reality be rounded. As such, the regions illustrated in the FIG. s are essentially schematic and are not intended to depict exact shapes, nor to limit the scope of the claimed disclosure.

Detailed reference will now be made to exemplary embodiments of the present disclosure, examples of which are illustrated in the accompanying drawings. Wherever possible, the same reference numerals are used throughout the drawings and description to refer to the same or like parts.

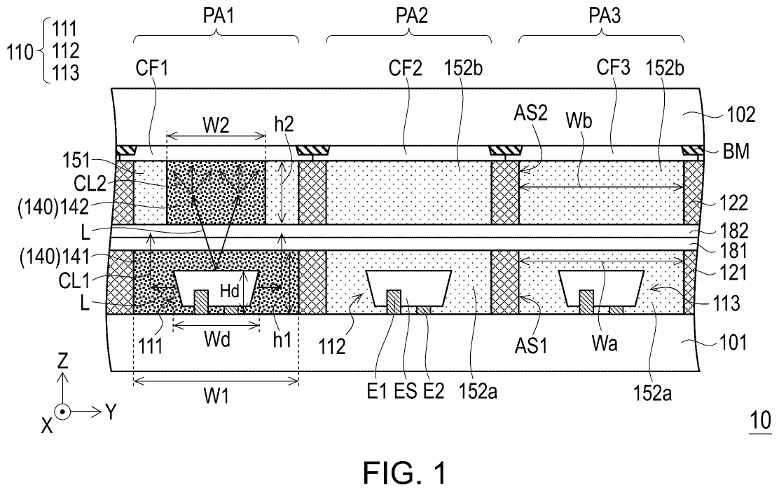

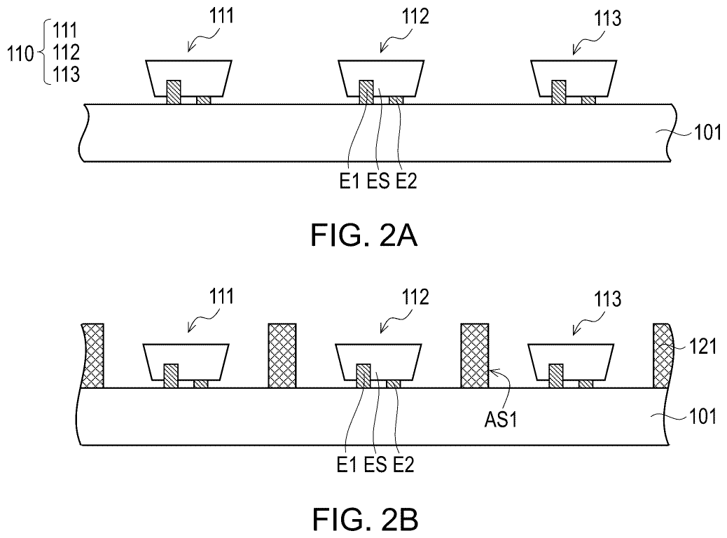

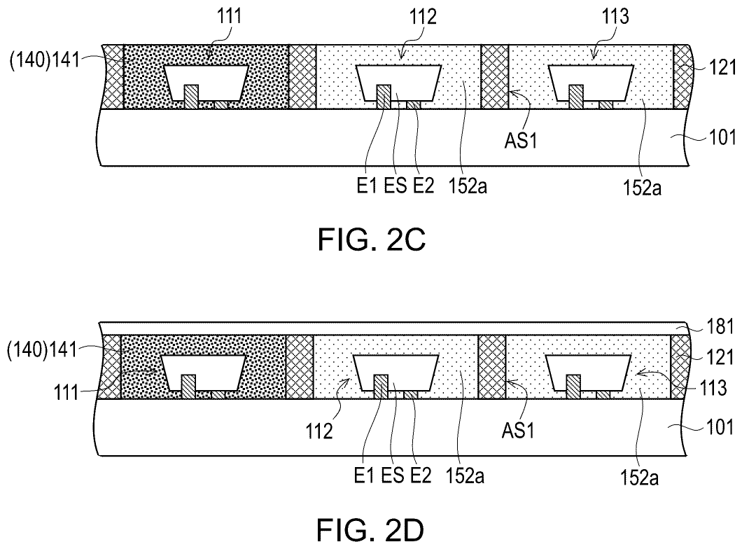

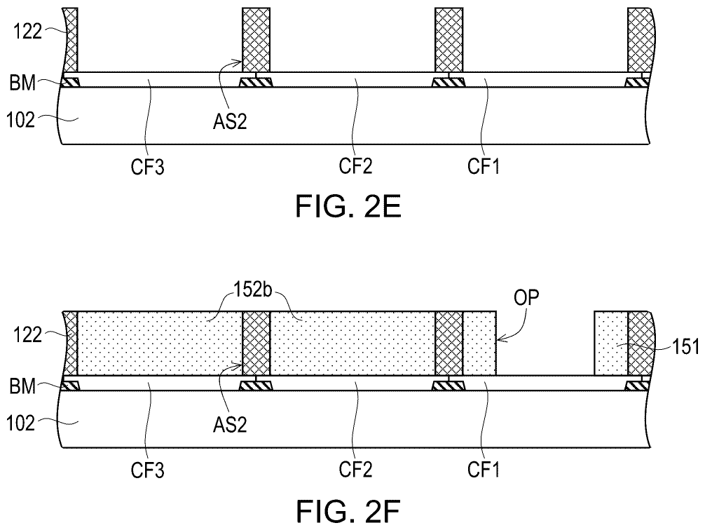

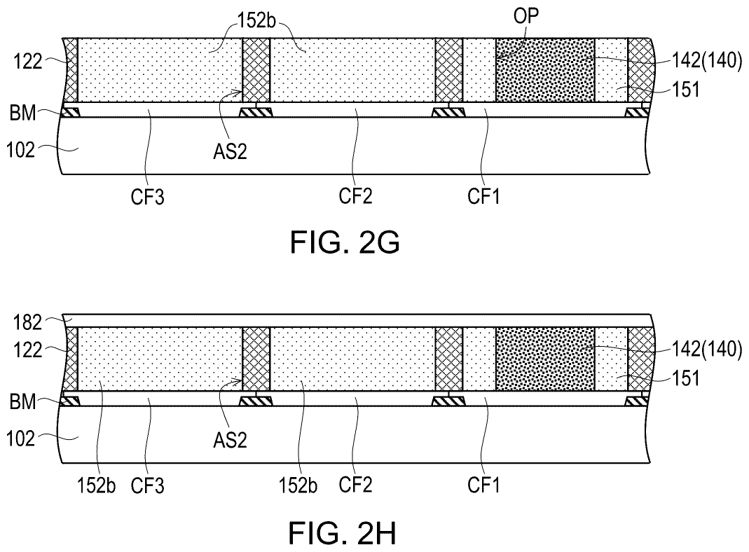

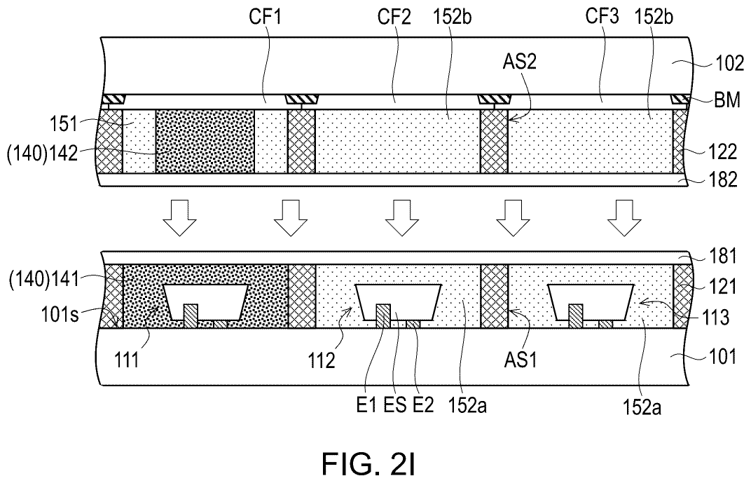

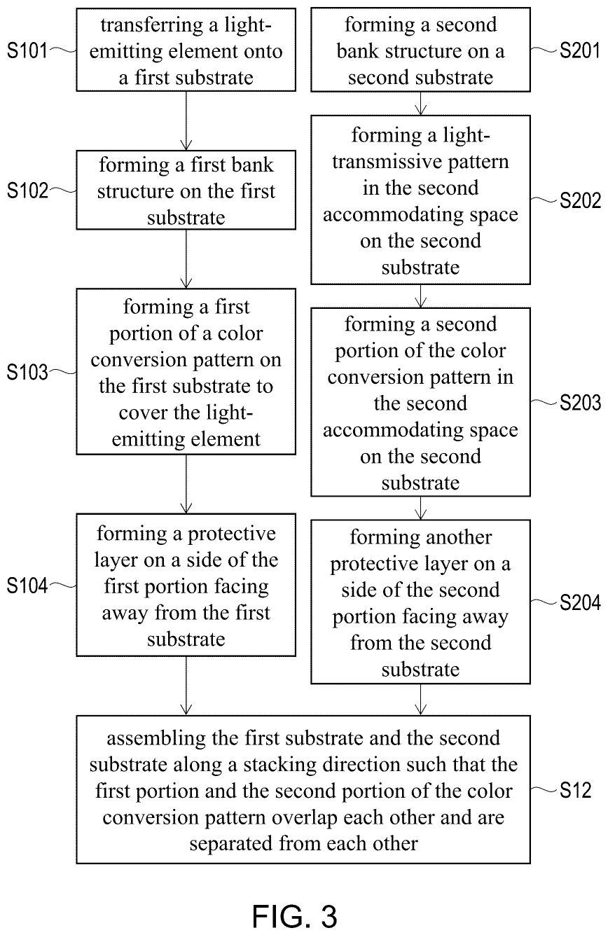

FIG. 1 is a schematic cross-sectional view of a display panel according to an embodiment of the disclosure. FIG. 2A to FIG. 2I are schematic cross-sectional views illustrating a manufacturing process of the display panel in FIG. 1. FIG. 3 is a block diagram illustrating the manufacturing process of the display panel in FIG. 1. Referring to FIG. 1, a display panel 10 includes a first substrate 101, a second substrate 102, a plurality of light-emitting elements 110, a first bank structure 121, and a second bank structure 122. The first substrate 101 and the second substrate 102 are stacked along a stacking direction (e.g., a direction Z). The materials of the first substrate 101 and the second substrate 102 may include glass, quartz, or other suitable substrates.

The first bank structure 121 is disposed on the first substrate 101 and defines a plurality of first accommodation spaces AS1. The second bank structure 122 is disposed on the second substrate 102 and defines a plurality of second accommodation spaces AS2. The plurality of first accommodation spaces AS1 respectively overlap the plurality of second accommodation spaces AS2 along the stacking direction of the two substrates. Hereinafter, unless otherwise specified, the overlapping relationship between two components is defined along the stacking direction of the first substrate 101 and the second substrate 102 (e.g., the direction Z in FIG. 1), and the overlapping direction will not be repeatedly described. On the other hand, in the embodiment, the first accommodation space AS1 and the second accommodation space AS2 respectively have a width Wa and a width Wb along any direction perpendicular to the stacking direction of the two substrates (e.g., a direction Y or a direction X), and the width Wa may be approximately equal to the width Wb, but the disclosure is not limited thereto.

More specifically, in the embodiment, the first bank structure 121 on the first substrate 101 may entirely overlap the second bank structure 122 on the second substrate 102. That is, an orthographic projection of the second bank structure 122 on the first substrate 101 is located within an orthographic projection of the first bank structure 121 on the first substrate 101.

From another perspective, the first bank structure 121 and the second bank structure 122 may define a plurality of pixel areas of the display panel 10, such as pixel areas PA1, PA2, and PA3. It should be noted that the number of pixel areas shown in FIG. 1 is three for illustrative purposes only, and does not imply that the display panel 10 has only three pixel areas. For example, in the embodiment, the display panel 10 may include a plurality of pixel areas arranged along the direction X and the direction Y. That is, these pixel areas are arranged in an array form on the first substrate 101.

The plurality of light-emitting elements 110 are disposed on the first substrate 101 and respectively located in the plurality of first accommodation spaces AS1. For example, the first substrate 101 may be an array substrate or circuit board provided with a pixel driving layer (not shown), and the plurality of light-emitting elements 110 may be bonded to the first substrate 101 be electrically connected to the pixel driving layer. In the embodiment, each of the light-emitting elements 110 may include an epitaxial structure layer ES, a first electrode E1, and a second electrode E2. The epitaxial structure layer ES may include a second-type semiconductor layer (not shown), a light-emitting layer (not shown), and a first-type semiconductor layer (not shown) sequentially stacked on the first substrate 101. The first electrode E1 and the second electrode E2 are electrically connected to the first-type semiconductor layer and the second-type semiconductor layer, respectively. It should be noted that the light-emitting element 110 in FIG. 1 is illustrated as a flip-chip type light-emitting element for exemplary purposes, but the disclosure is not limited thereto. In other embodiments, the light-emitting element 110 may be a lateral type or vertical type light-emitting element.

In the embodiment, the three first accommodation spaces AS1 corresponding to the pixel areas PA1, PA2, and PA3 may be respectively provided with a light-emitting element 111, a light-emitting element 112, and a light-emitting element 113, and these three light-emitting elements may emit different colors of light. For example, in the embodiment, the light-emitting element 111 in pixel area PA1 and the light-emitting element 113 in pixel area PA3 may emit the same color light, such as blue light, while the light-emitting element 112 in pixel area PA2 may emit green light, but the disclosure is not limited thereto. In other embodiments, the light-emitting element 112 may also emit blue light like the light-emitting element 111 and the light-emitting element 113.

In the embodiment, the display colors of the pixel area PA1, the pixel area PA2, and the pixel area PA3 may be red, green, and blue, respectively, but the disclosure is not limited thereto. Since the light-emitting element 111 in pixel area PA1 emits blue light, a color conversion pattern 140 is also provided in pixel area PA1 of the display panel 10. The material of the color conversion pattern 140 may include quantum dot materials (e.g., Group II-IV, III-V, IV-VI, or Group IV semiconductors), inorganic phosphor materials (e.g., Yttrium Aluminum Garnet (YAG)-based phosphors, Terbium Aluminum Garnet (TAG)-based phosphors, Sialon-based phosphors, Mn4+-activated fluoride complex phosphors, etc.), organic phosphor materials, or phosphorescent materials, but the disclosure is not limited thereto.

More specifically, the color conversion pattern 140 is provided in the first accommodation space AS1 and the second accommodation space AS2. The color conversion pattern 140 is disposed between the first substrate 101 and the second substrate 102 and includes a first portion 141 and a second portion 142. In detail, the first portion 141 is disposed on the first substrate 101 and covers the light-emitting element 111 located in the pixel area PA1. That is, the first portion 141 is filled in the first accommodation space AS1 corresponding to the pixel area PA1. The second portion 142 is disposed on the second substrate 102 and located in the second accommodation space AS2 corresponding to the pixel area PA1.

It should be particularly noted that the first portion 141 and the second portion 142 of the color conversion pattern 140 overlap each other along the direction Z (i.e., the stacking direction of the two substrates) and are separated from each other. In the embodiment, the light-emitting element 111 is covered by the first portion 141 of the color conversion pattern 140, and the light-emitting element 111 is completely overlapped with the second portion 142 of the color conversion pattern 140 in the stacking direction of the two substrates. In other words, an orthogonal projection of the second portion 142 of the color conversion pattern 140 on the first substrate 101 is located within an orthogonal projection of the light-emitting element 111 on the first substrate 101.

From another perspective, the light-emitting element 111 and the first portion 141 and the second portion 142 of the color conversion pattern 140 respectively have an element width Wd, a width W1, and a width W2 along any direction (e.g., the direction Y or the direction X) perpendicular to the direction Z (i.e., the stacking direction of the two substrates). The width W2 of the second portion 142 is less than the width W1 of the first portion 141 and greater than the element width Wd of the light-emitting element 111. Preferably, a ratio of the width W2 to the width W1 is less than or equal to 0.95, and a ratio of the width W2 to the element width Wd is greater than or equal to 1.2.

More specifically, the second portion 142 does not fully fill the second accommodation space AS2 corresponding to the pixel area PA1, and in the direction Z, the second portion 142 does not overlap a part of the first portion 141 surrounding the sidewall of the light-emitting element 111. That is, in the stacking direction of the two substrates, the part of the first portion 141 surrounding the sidewall of the light-emitting element 111 is not blocked by the second portion 142.

For example, a light L emitted from the light-emitting element 111 toward the second portion 142 is converted (i.e., wavelength-converted) by the second portion 142 to form a converted light CL2, which may directly exit the color conversion pattern 140 toward the second substrate 102. Notably, the light L emitted from the sidewall of the light-emitting element 111, after being converted by the part of the first portion 141 surrounding the sidewall, forms a converted light CL1, which does not pass through the second portion 142 of the color conversion pattern 140 during transmission toward the second substrate 102 (i.e., the converted light CL1 is not blocked by the second portion 142). In other words, the optical path length of the converted light CL2 from its formation to its exit from the color conversion pattern 140 is comparable to that of the converted light CL1. Thus, the issue of reduced light extraction efficiency caused by the high-thickness design of conventional color conversion patterns for achieving good light conversion efficiency can be effectively improved.

In the embodiment, the display panel 10 may be provided with a light-transmissive pattern in the second accommodation space AS2. For example, in the second accommodation space AS2 corresponding to the pixel area PA1, a light-transmissive pattern 151 may be disposed between the second portion 142 of the color conversion pattern 140 and the second bank structure 122, and the light-transmissive pattern 151 has good transmittance for both the converted light CL1 from the first portion 141 and the converted light CL2 from the second portion 142. More specifically, in the stacking direction of the two substrates, the light-transmissive pattern 151 overlaps the first portion 141 of the color conversion pattern 140, but does not overlap the light-emitting element 111.

On the other hand, in the embodiment, the light-emitting element 112 located in the pixel area PA2 emits green light, and the light-emitting element 113 located in the pixel area PA3 emits blue light. Therefore, no color conversion pattern is provided in the pixel areas PA2 and PA3. Instead, a light-transmissive pattern 152a and a light-transmissive pattern 152b are respectively filled in the first accommodation space AS1 and the second accommodation space AS2 corresponding to the pixel area PA2 or the pixel area PA3. The light-transmissive pattern 152a and the light-transmissive pattern 152b have good transmittance for the green light and the blue light.

The material of the light-transmissive pattern may include an inorganic material (e.g., silicon oxide, silicon nitride, silicon oxynitride, other suitable materials, or a stacked layer of at least two of the above), an organic material (e.g., polyester (PET), polyolefin, polyacrylate, polycarbonate, polyalkylene oxide, polystyrene, polyether, polyketone, polyalcohol, polyaldehyde, or other suitable materials, or combinations thereof), or other suitable materials or combinations thereof. In the embodiment, the materials of the light-transmissive patterns provided for different pixel areas may be the same or different.

It is particularly noted that, in the stacking direction of the two substrates, the light-emitting element 111 has an element height Hd, and the first portion 141 and the second portion 142 of the color conversion pattern 140 respectively have a thickness t1 and a thickness t2. To achieve good color conversion efficiency, the color conversion pattern 140 between a forward light-emitting surface of the light-emitting element 111 and the second substrate 102 must have sufficient thickness (e.g., greater than 12 μm). In the embodiment, the element height Hd of the light-emitting element 111 is, for example, 8 μm. If a conventional monolithic bank structure design is adopted, the height of the bank structure would have to be at least 20 μm, which would significantly increase the process complexity and adversely affect the production yield of the display panel.

To address the above issue, in the display panel 10 of the embodiment, the bank structure is composed of the first bank structure 121 and the second bank structure 122 respectively disposed on the first substrate 101 and the second substrate 102. Correspondingly, the color conversion pattern 140 is composed of the first portion 141 and the second portion 142 respectively disposed on the first substrate 101 and the second substrate 102. Therefore, the height of the bank structure on each substrate can be significantly reduced. For example, a height h1 of the first bank structure 121 and a height h2 of the second bank structure 122 can each be 10 μm to meet the thickness requirement of the color conversion pattern 140 above the forward light-emitting surface of the light-emitting element 111. In other words, the segmented design of the bank structure and the color conversion pattern can avoid the need for excessively tall bank structure to define the accommodation space, thereby reducing process difficulty. That is to say, such a segmented design can increase the process margin of the display panel 10 and improve its production yield.

According to process requirements, a protective layer 181 and a protective layer 182 may further be provided between the first portion 141 and the second portion 142 of the color conversion pattern 140. Therefore, in the embodiment, the first portion 141 and the second portion 142 of the color conversion pattern 140 are separated from each other. The material of the protective layer 181 and the protective layer 182 may include inorganic materials (e.g., SiO₂ or SiNx), but the disclosure is not limited thereto.

To enhance the color performance (e.g., color purity) of the display panel 10, a color filter layer may further be provided on the second substrate 102. In the embodiment, the color filter layer may include a filter pattern CF1, a filter pattern CF2, and a filter pattern CF3 respectively corresponding to the pixel area PA1, the pixel area PA2, and the pixel area PA3. These filter patterns CF1 to CF3 are respectively adapted to transmit red light, green light, and blue light, but the disclosure is not limited thereto. In addition to allowing red light to pass through, the filter pattern CF1 can also absorb light L that has not been converted by the color conversion pattern 140, thereby preventing blue light L from leaking and affecting the color purity of the pixel area PA1. To prevent light in each pixel area from leaking into adjacent pixel areas and degrading display quality, a black matrix layer BM may further be provided on the second substrate 102. The black matrix layer BM has a plurality of openings corresponding to the plurality of pixel areas. The aforementioned filter patterns of the color filter layer are disposed corresponding to the openings of the black matrix layer BM.

The following describes an exemplary method of fabricating the display panel 10.

First, transferring a plurality of light-emitting elements 110 onto a first substrate 101 (i.e., step S101 in FIG. 3), as shown in FIG. 2A. For example, in the embodiment, these light-emitting elements 110 may be a plurality of micro light-emitting diodes (micro-LEDs), and the transfer step may be performed by a mass transfer process, but the disclosure is not limited thereto. After the transfer of the plurality of light-emitting elements 110 is completed, forming a first bank structure 121 on the first substrate 101 (i.e., step S102 in FIG. 3), wherein the plurality of light-emitting elements 110 are respectively located in the plurality of first accommodation spaces AS1 of the first bank structure 121, as shown in FIG. 2B.

Next, forming a first portion 141 of a color conversion pattern 140 on the first substrate 101 to cover the light-emitting element 111 (i.e., step S103 in FIG. 3), as shown in FIG. 2C. In the embodiment, the method of fabricating the display panel 10 in FIG. 1 may further include forming two light-transmissive patterns 152a on the first substrate 101 to cover the light-emitting element 112 and the light-emitting element 113. After forming the first portion 141 of the color conversion pattern 140 and the light-transmissive patterns 152a, forming a protective layer 181 on a side of the first portion 141 facing away from the first substrate 101 (i.e., step S104 in FIG. 3), as shown in FIG. 2D. In the embodiment, the protective layer 181 may be an inorganic material layer (e.g., a SiNx layer or a SiO₂ layer) formed by chemical vapor deposition (CVD) or other suitable processes, but the disclosure is not limited thereto. At this point, the film layers on the first substrate 101 are completed.

On the other hand, the method of fabricating the display panel 10 in FIG. 1 further includes forming a second bank structure 122 on a second substrate 102 (i.e., step S201 in FIG. 3), wherein the second bank structure 122 defines a plurality of second accommodation spaces AS2, as shown in FIG. 2E. In the embodiment, a black matrix layer BM and a color filter layer including a plurality of filter patterns CF1 to CF2 may be formed on the second substrate 102 before forming the second bank structure 122, but the disclosure is not limited thereto.

After the fabrication of the second bank structure 122 is completed, forming a plurality of light-transmissive patterns in the plurality of second accommodation spaces AS2 on the second substrate 102 (i.e., step S202 in FIG. 3), as shown in FIG. 2F. For example, a light-transmissive pattern 151 having an opening OP is formed in the second accommodation space AS2 corresponding to the filter pattern CF1, and two light-transmissive patterns 152b are respectively formed in the second accommodation spaces AS2 corresponding to the filter patterns CF2 and CF3. Next, as shown in FIG. 2G, forming a second portion 142 of the color conversion pattern 140 in the second accommodation space AS2 corresponding to the filter pattern CF1 on the second substrate 102 (i.e., step S203 in FIG. 3), wherein the second portion 142 is filled in the opening OP of the light-transmissive pattern 151.

After the second portion 142 of the color conversion pattern 140 is formed, forming another protective layer 182 on a side of the second portion 142 facing away from the second substrate 102 (i.e., step S204 in FIG. 3), as shown in FIG. 2H. In the embodiment, the protective layer 182 may be an inorganic material layer (e.g., a SiNx layer or a SiO₂ layer) formed by chemical vapor deposition (CVD) or other suitable processes, but the disclosure is not limited thereto. At this point, the fabrication of the film layers on the second substrate 102 is completed.

Referring to FIG. 2I, after the film layers on the first substrate 101 and the second substrate 102 are completed, assembling the first substrate 101 and the second substrate 102 along the stacking direction such that the first portion 141 and the second portion 142 of the color conversion pattern 140 overlap each other and are separated from each other (i.e., step S12 in FIG. 3). The stacking direction herein is, for example, a normal direction of a substrate surface 101s of the first substrate 101. After the assembly of the first substrate 101 and the second substrate 102, the light-transmissive pattern 151 in the pixel area PA1 does not overlap the light-emitting element 111 in the stacking direction, but overlaps the first portion 141 of the color conversion pattern 140.

It is particularly noted that, after the assembly of the first substrate 101 and the second substrate 102, the protective layer 181 on the first substrate 101 is connected to the protective layer 182 on the second substrate 102, and the protective layer 181 and the protective layer 182 are located between the first portion 141 and the second portion 142 of the color conversion pattern 140. In other words, the first portion 141 and the second portion 142 of the color conversion pattern 140 in the embodiment are separated by the protective layer 181 and the protective layer 182 connected to each other. At this point, the fabrication of the display panel 10 shown in FIG. 1 is completed.

Referring to FIG. 1, in the embodiment, the display panel 10 includes a first substrate 101, a second substrate 102, a first bank structure 121, a second bank structure 122, a light-emitting element 111, and a color conversion pattern 140. The first substrate 101 and the second substrate 102 are stacked over each other along a stacking direction (e.g., the direction Z). The first bank structure 121 is disposed on the first substrate 101 and defines a first accommodation space AS1 for accommodating the light-emitting element 111 and the first portion 141 of the color conversion pattern 140. The second bank structure 122 is disposed on the second substrate 102 and defines a second accommodation space AS2 for accommodating the second portion 142 of the color conversion pattern 140. The first portion 141 and the second portion 142 of the color conversion pattern 140 respectively have a width W1 and a width W2 along a direction perpendicular to the stacking direction of the two substrates, and the width W2 is less than the width W1.

In summary, in a display panel according to an embodiment of the disclosure, a color conversion pattern is provided on a light-emitting side of a light-emitting element, and the color conversion pattern is composed of a first portion and a second portion that are separated from each other. The first portion directly covers the light-emitting element on the first substrate. The overlapping relationship among the first portion, the second portion, and the light-emitting element along a stacking direction of the first substrate and the second substrate ensures the color conversion efficiency of the display panel. In a direction perpendicular to the stacking direction, since a width of the second portion is less than a width of the first portion, a part of the first portion surrounding the sidewall of the light-emitting element is not blocked by the second portion. As such, the converted light generated by the light emitted from the light-emitting element and passing through the part of the first portion is not blocked by the second portion, thereby effectively improving the overall light extraction efficiency of the display panel. On the other hand, since the first portion and the second portion of the color conversion pattern are respectively formed on the first substrate and the second substrate, an excessive height of the bank structure used to define the accommodating space can be avoided, thereby reducing manufacturing complexity. In other words, the segmented design of the color conversion pattern increases the process margin of the display panel, thereby improving its production yield.

What is claimed is:

1. A display panel, comprising:
a first substrate and a second substrate, overlapping each other along a stacking direction;
a first bank structure, disposed on the first substrate and defining a first accommodation space;
a second bank structure, disposed on the second substrate and defining a second accommodation space;
a light-emitting element, disposed on the first substrate and located in the first accommodation space; and
a color conversion pattern, disposed between the first substrate and the second substrate, and comprising a first portion and a second portion overlapping each other and separated from each other, wherein the first portion is disposed on the first substrate and covers the light-emitting element, the second portion is disposed on the second substrate and located in the second accommodation space, the first portion and the second portion respectively have a first width and a second width in a direction perpendicular to the stacking direction, and the second width is less than the first width.

2. The display panel according to claim 1, wherein a width of the first accommodation space along the direction is equal to a width of the second accommodation space along the direction.

3. The display panel according to claim 1, further comprising:
a light-transmissive pattern, disposed in the second accommodation space, wherein the light-transmissive pattern does not overlap the light-emitting element along the stacking direction.

4. The display panel according to claim 3, wherein the light-transmissive pattern overlaps the first portion of the color conversion pattern along the stacking direction.

5. The display panel according to claim 1, wherein a ratio of the second width to the first width is less than or equal to 0.95.

6. The display panel according to claim 1, wherein the light-emitting element has an element width along the direction, and a ratio of the second width to the element width is greater than or equal to 1.2.

7. The display panel according to claim 1, wherein a protective layer is provided between the first portion and the second portion of the color conversion pattern.

8. A method of fabricating a display panel, comprising:
transferring a light-emitting element onto a first substrate;
forming a first bank structure on the first substrate, wherein the light-emitting element is located in a first accommodation space defined by the first bank structure;
forming a second bank structure on a second substrate, wherein the second bank structure defines a second accommodation space;
forming a first portion of a color conversion pattern on the first substrate to cover the light-emitting element;
forming a second portion of the color conversion pattern in the second accommodation space on the second substrate; and
assembling the first substrate and the second substrate along a stacking direction such that the first portion and the second portion of the color conversion pattern overlap each other and are separated from each other, wherein the first portion and the second portion respectively have a first width and a second width along a direction perpendicular to the stacking direction, and the second width is less than the first width.

9. The method of fabricating the display panel according to claim 8, further comprising:
forming a light-transmissive pattern in the second accommodation space on the second substrate.

10. The method of fabricating the display panel according to claim 9, wherein, after the first substrate and the second substrate are assembled, the light-transmissive pattern does not overlap the light-emitting element along the stacking direction.

11. The method of fabricating the display panel according to claim 10, wherein the light-transmissive pattern overlaps the first portion of the color conversion pattern along the stacking direction after the first substrate and the second substrate are assembled.

12. The method of fabricating the display panel according to claim 8, further comprising:
forming a protective layer on a side of the first portion facing away from the first substrate or on a side of the second portion facing away from the second substrate.

13. The method of fabricating the display panel according to claim 12, wherein the protective layer is disposed between the first portion and the second portion of the color conversion pattern after the first substrate and the second substrate are assembled.

14. The method of fabricating the display panel according to claim 8, wherein a ratio of the second width to the first width is less than or equal to 0.95.

15. The method of fabricating the display panel according to claim 8, wherein the light-emitting element has an element width along the direction, and a ratio of the second width to the element width is greater than or equal to 1.2.
